(19) United States
(12) Patent Application Publication
(10) Pub. No.: US 2026/0075765 A1
(43) Pub. Date: Mar. 12, 2026

(54) VEHICLE SYSTEM INCLUDING AUTOMOTIVE STORAGE DEVICE AND VEHICLE INCLUDING THE SAME

(71) Applicant: Samsung Electronics Co., Ltd., Suwon-si (KR)

(72) Inventors: Seungcheol LEE, Suwon-si (KR); Jinwook LEE, Suwon-si (KR)

(73) Assignee: Samsung Electronics Co., Ltd., Suwon-si (KR)

(21) Appl. No.: 19/273,852

(22) Filed: Jul. 18, 2025

(30) Foreign Application Priority Data
Sep. 10, 2024 (KR) 10-2024-0123373

(51) Int. Cl. H05K 7/20; G06F 1/20; H01M 10/613; H01M 10/625; H01M 10/633; H01M 10/6569; H01M 10/663; H01M 10/667

(52) U.S. Cl. CPC H05K 7/20327; G06F 1/20; H01M 10/613; H01M 10/625; H01M 10/633; H01M 10/6569; H01M 10/663; H01M 10/667; G06F 2200/201

(57) ABSTRACT

A vehicle system may include a heat management system configured to control the first valve with respect to connecting a battery pack cooling line to a automotive storage device cooling line and a radiator cooling line to a first chiller cooling line that is connected to the battery pack cooling line, and to control the second valve with respect to connecting a motor cooling line to the radiator cooling line, in response to a temperature of a vehicle is higher than a first threshold temperature.

### CROSS-REFERENCE TO RELATED APPLICATION

This application claims priority to and the benefit of Korean Patent Application No. 10-2024-0123373 filed in the Korean Intellectual Property Office on Sep. 10, 2024, the entire contents of which are incorporated herein by reference.

### BACKGROUND

### (a) Field of the Invention

Inventive concepts relate to a vehicle system including an automotive storage device and/or to a vehicle including the same.

### (b) Description of the Related Art

A vehicle may include an automotive storage device for storing data generated in the vehicle, such as a solid state drive (SSD). The data stored in the automotive storage device may have increased error bits based on a temperature of the vehicle. The automotive storage device may have its operation performance limited by the temperature of the vehicle. A vehicle system for controlling the temperature of the vehicle may control connection between cooling lines through which a coolant may flow such that the automotive storage device may be operated within a temperature range that allows its relatively smooth operation.

### SUMMARY

Inventive concepts relate to a vehicle system for controlling a temperature of an automotive storage device and/or to a vehicle including the same.

According to some example embodiments a vehicle system may include a first valve configured to connect to each other two or more cooling lines among a battery pack cooling line, an automotive storage device cooling line, a motor cooling line that is connected to the automotive storage device cooling line, a radiator cooling line, a first chiller cooling line, and a second chiller cooling line; a second valve configured to connect the motor cooling line to an automotive storage device heating line or to the radiator cooling line; and a heat management system configured to control the first valve with respect to connecting the battery pack cooling line to the automotive storage device cooling line and connecting the radiator cooling line to the first chiller cooling line, the first chiller cooling line being connected to the battery pack cooling line, and is further configured to control the second valve with respect to connecting the motor cooling line to the radiator cooling line, in response to a temperature of a vehicle being higher than a first threshold temperature.

According to some example embodiments a vehicle system may include a first valve connecting connecting to each other two or more of cooling lines among a battery pack cooling line, an automotive storage device cooling line, a motor cooling line, a radiator cooling line, and a chiller cooling line; a second valve connecting the motor cooling line to an automotive storage device heating line or to the radiator cooling line; and a heat management system configured to control the first valve and the second valve with respect to circulating coolant through the cooling lines toin order of the motor cooling line, the automotive storage device heating line, the radiator cooling line, a first chiller cooling line, the battery pack cooling line, and the motor cooling line, in response to a temperature of a vehicle being lower than a first threshold temperature.

According to some example embodiments, a vehicle may include a first valve connecting two or more of cooling lines among a battery pack cooling line, an automotive storage device cooling line, a motor cooling line, a radiator cooling, and a chiller cooling line; a second valve connecting the motor cooling line to an automotive storage device heating line or to the radiator cooling line; a vehicle control unit configured to generate first path information with respect to connecting the battery pack cooling line to the automotive storage device cooling line, connecting the motor cooling line to the radiator cooling line, the motor cooling line being connected to the automotive storage device cooling line, and connecting the radiator cooling line to a first chiller cooling line, the first chiller cooling line being connected to the battery pack cooling line, in response to a temperature of the vehicle being higher than a first threshold temperature; and a heat management system configured to control the first valve and the second valve with respect to circulating coolant through the cooling lines based on the first path information.

### BRIEF DESCRIPTION OF THE DRAWINGS

FIG. 1 is a view for explaining a vehicle according to some example embodiments.

FIG. 2 is a view for explaining cooling lines and heating lines according to some example embodiments.

FIG. 3 is a view for explaining a vehicle control unit and a heat management system for controlling a temperature of the vehicle according to some example embodiments.

FIG. 4 is a view for explaining a vehicle system for controlling a first multi-way valve and a second multi-way valve based on the temperature of the vehicle that is lower than a first threshold temperature according to some example embodiments.

FIG. 5 is a view for explaining the vehicle system for controlling the first multi-way valve and the second multi-way valve based on the temperature of the vehicle that is higher than the first threshold temperature and lower than a second threshold temperature according to some example embodiments.

FIG. 6 is a view for explaining the vehicle system for controlling the first multi-way valve and the second multi-way valve based on the temperature of the vehicle that is higher than the second threshold temperature and lower than a third threshold temperature according to some example embodiments.

FIG. 7 is a view for explaining the vehicle system for controlling the first multi-way valve and the second multi-way valve based on the temperature of the vehicle that is higher than the third threshold temperature according to some example embodiments.

FIG. 8 is a flowchart for explaining the vehicle system for generating path information according to some example embodiments.

FIG. 9 is a flowchart for explaining the vehicle system for controlling the first multi-way valve and the second multi-way valve based on the temperature of the vehicle according to some example embodiments.

FIG. 10 is a view for explaining an automotive storage device according to some example embodiments.

### DETAILED DESCRIPTION

Hereinafter, various example embodiments of the inventive concepts are described in detail with reference to the accompanying drawings so that those ordinarily skilled in the art to which the inventive concepts pertain may easily practice the inventive concepts. Inventive concepts may be implemented in various different forms and are not limited to the example embodiments described herein.

Same or similar components are denoted by the same reference numeral throughout the specification.

In addition, when a part “includes” any component, it may indicate the inclusion of other components rather than the exclusion of other components unless explicitly described to the contrary.

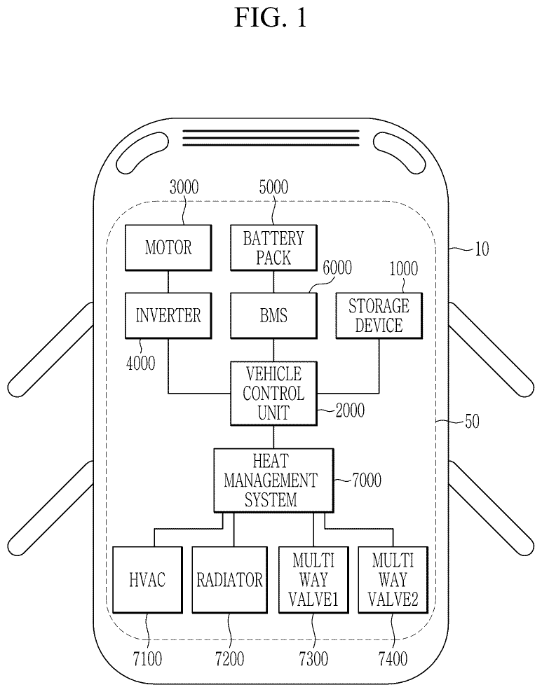

FIG. 1 is a view illustrating a vehicle according to some example embodiments.

Referring to FIG. 1, a vehicle 10 may include a vehicle system 50. The vehicle system 50 may include an automotive storage device 1000, a vehicle control unit 2000, a motor 3000, an inverter 4000, a battery pack 5000, a battery management system (BMS) 6000, a heat management system 7000, a heat, ventilating, and air conditioning (HVAC) system 7100, a radiator 7200, a first multi-way valve 7300, and a second multi-way valve 7400.

In some example embodiments, the automotive storage device 1000 may store data generated in the vehicle 10. In some example embodiments, the automotive storage device 1000 may be a solid state drive (SSD), but inventive concepts are not limited thereto.

In some example embodiments, the vehicle control unit 2000 may control overall operations of the vehicle. In some example embodiments, the vehicle control unit 2000 may control the inverter 4000 to cause the motor 3000 to perform a rotational motion. In some example embodiments, the vehicle control unit 2000 may control the heat management system 7000 with respect to decreasing temperature of the automotive storage device 1000, a temperature of the motor 3000, and/or a temperature of the battery pack 5000 based on (for example, in response to) a temperature of the vehicle 10.

In some example embodiments, the motor 3000 may be connected to a wheel of the vehicle 10. The motor 3000 may rotate the wheel of the vehicle 10 based on a driving voltage applied by the inverter 4000.

In some example embodiments, the inverter 4000 may convert a voltage of the battery pack 5000 to the driving voltage, and apply the driving voltage to the motor 3000.

In some example embodiments, the battery pack 5000 may store electric energy used to drive the vehicle 10.

In some example embodiments, the battery management system (BMS) 6000 may control a state of the battery pack. In some example embodiments, the battery management system 6000 may measure the voltage, current, and/or temperature of the battery pack 5000, and/or generate state of charge (SOC) information of the battery pack 5000 based on the voltage, current, and/or temperature of the battery pack 5000. In some example embodiments, the battery management system 6000 may detect a fault in the battery pack 5000 based on the SOC information.

In some example embodiments, the battery management system 7000 may control the temperature of the vehicle 10. The temperature of the vehicle 10 may be determined based on an external temperature of the vehicle 10, the temperature of the automotive storage device 1000, the temperature of the motor 3000, and/or the temperature of the battery pack 5000. In some example embodiments, the heat management system 7000 may be operated under the control of the vehicle control unit 2000. In some example embodiments, the heat management system 7000 may drive the HVAC system 7100 and the radiator 7200 based on the temperature of the vehicle 10.

In some example embodiments, the automotive storage device 1000, the motor 3000, the inverter 4000, the battery pack 5000, the HVAC system 7100, the radiator 7200, the first multi-way valve 7300, and the second multi-way valve 7400 may be connected to one another through cooling lines and/or heating lines. In some example embodiments, a coolant may flow through the cooling lines and/or the heating lines. The coolant may absorb heat and/or release heat while passing through the automotive storage device 1000, the motor 3000, the inverter 4000, the battery pack 5000, the HVAC system 7100, and the radiator 7200.

In some example embodiments, the heat management system 7000 may control the connection between the cooling lines and/or the heating lines connected to the automotive storage device 1000, the motor 3000, the inverter 4000, the battery pack 5000, the HVAC system 7100, the radiator 7200, the first multi-way valve 7300, and the second multi-way valve 7400, based on the temperature of the vehicle 10.

In some example embodiments, the heat management system 7000 may control the first multi-way valve 7300 based on the temperature of the vehicle 10 for (for example, with respect to) some among the cooling lines and/or the heating lines connected to the automotive storage device 1000, the cooling line connected to the motor 3000 and the inverter 4000, the cooling line connected to the battery pack 5000, the cooling line connected to the HVAC system 7100, and the cooling line connected to the radiator 7200 to be connected to each other.

In some example embodiments, the heat management system 7000 may control the second multi-way valve 7400 based on the temperature of the vehicle 10 for (for example, with respect to) the cooling line connected to the motor 3000 and the inverter 4000 to be connected to the heating line connected to the automotive storage device 1000 or the cooling line connected to the radiator 7200.

In some example embodiments, the HVAC system 7100 may control the heating, ventilation, and/or air conditioning of the vehicle 10. In some example embodiments, the HVAC system 7100 may be driven under control of the heat management system 7000.

In some example embodiments, the radiator 7200 may cool the coolant by releasing heat absorbed by the coolant flowing through the cooling lines. In some example embodiments, the radiator 7200 may be driven under the control of the heat management system 7000.

In some example embodiments, the first multi-way valve 7300 may be connected to the cooling line connected to the automotive storage device 1000, the cooling line connected to the motor 3000 and the inverter 4000, the cooling line connected to the battery pack 5000, and the cooling line connected to the HVAC system 7100.

In some example embodiments, the second multi-way valve 7400 may be connected to the cooling line connected to the motor 3000 and the inverter 4000, the heating line connected to the automotive storage device 1000, and the cooling line connected to the radiator 7200.

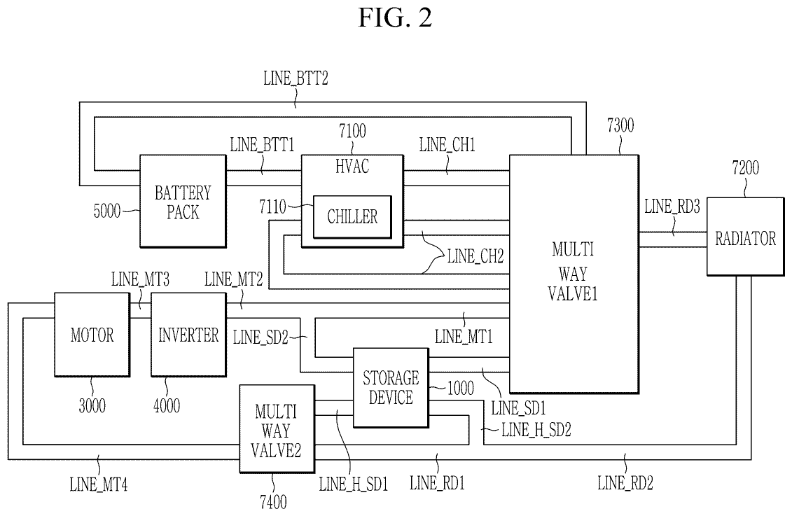

FIG. 2 is a view for explaining the cooling lines and the heating lines according to some example embodiments.

Referring to FIG. 2, in some example embodiments, the automotive storage device 1000, the motor 3000, the inverter 4000, the battery pack 5000, the HVAC system 7100, the radiator 7200, the first multi-way valve 7300, and the second multi-way valve 7400 may be connected to one another through the cooling lines and/or the heating lines. In some example embodiments, the HVAC system 7100 may include a chiller 7110. In some example embodiments, the chiller 7110 may cool the coolant flowing through the cooling lines and/or the heating lines. In some example embodiments, the chiller 7110 may have a greater cooling capacity than the radiator 7200 to cool the coolant, but inventive concepts are not limited thereto.

In some example embodiments, the cooling lines may include the cooling lines of (for example, connected to) the automotive storage device 1000, the cooling lines of the motor 3000, the cooling lines of the battery pack 5000, the cooling lines of the chiller 7110, and the cooling lines of the radiator 7200. In some example embodiments, the heating lines may include the heating lines (for example, connected to) of the automotive storage device 1000.

In some example embodiments, the cooling lines of (for example, connected to) the battery pack 5000 may include a first battery pack cooling line LINE_BTT1 and a second battery pack cooling line LINE_BTT2. In some example embodiments, the first battery pack cooling line LINE_BTT1 and the second battery pack cooling line LINE_BTT2 may be connected to each other through (for example, by) the battery pack 5000.

In some example embodiments, the first battery pack cooling line LINE_BTT1 may be connected to the HVAC system 7100. In some example embodiments, the second battery pack cooling line LINE_BTT2 may be connected to the first multi-way valve 7300. In some example embodiments, the coolant flowing from the first battery pack cooling line LINE_BTT1 to the second battery pack cooling line LINE_BTT2 may transfer heat to the battery pack 5000 and/or absorb heat from the battery pack 5000.

In some example embodiments, the cooling lines of (for example, connected to) the chiller 7110 may include a first chiller cooling line LINE_CH1 and a second chiller cooling line LINE_CH2. In some example embodiments, the first chiller cooling line LINE_CH1 may be connected to the first battery pack cooling line LINE_BTT1 through (for example, by) the HVAC system 7100. In some example embodiments, the first chiller cooling line LINE_CH1 and the second chiller cooling line LINE_CH2 may be connected to the first multi-way valve 7300. In some example embodiments, the chiller 7110 may cool the coolant flowing from the first chiller cooling line LINE_CH1 to the first battery pack cooling line LINE_BTT1. In some example embodiments, the chiller 7110 may cool the coolant flowing through the second chiller cooling line LINE_CH2.

In some example embodiments, the cooling lines of (for example, connected to) the automotive storage device 1000 may include a first automotive storage device cooling line LINE_SD1 and a second automotive storage device cooling line LINE_SD2. The first automotive storage device cooling line LINE_SD1 and the second automotive storage device cooling line LINE_SD2 may be connected to each other through (for example, by) the automotive storage device 1000.

The first automotive storage device cooling line LINE_SD1 may be connected to the first multi-way valve 7300. The second automotive storage device cooling line LINE_SD2 may be connected to a first motor cooling line LINE_MT1 and a second motor cooling line LINE_MT2. In some example embodiments, the coolant flowing from the first automotive storage device cooling line LINE_SD1 to the second automotive storage device cooling line LINE_SD2 may absorb heat from the automotive storage device 1000.

In some example embodiments, the heating lines of (for example, connected to) the automotive storage device 1000 may include a first automotive storage device heating line LINE_H_SD1 and a second automotive storage device heating line LINE_H_SD2. The first automotive storage device heating line LINE_H_SD1 and the second automotive storage device heating line LINE_H_SD2 may be connected to each other through (for example, by) the automotive storage device 1000.

In some example embodiments, the first automotive storage device heating line LINE_H_SD1 may be connected to the second multi-way valve 7400. In some example embodiments, the second automotive storage device heating line LINE_H_SD2 may be connected to a first radiator cooling line LINE_RD1 and a second radiator cooling line LINE_RD2. In some example embodiments, the coolant flowing from the first automotive storage device heating line LINE_H_SD1 to the second automotive storage device heating line LINE_H_SD2 may transfer heat to the automotive storage device 1000.

In some example embodiments, the cooling lines of (for example, connected to) the motor 3000 may include the first motor cooling line LINE_MT1, the second motor cooling line LINE_MT2, a third motor cooling line LINE_MT3, and a fourth motor cooling line LINE_MT4.

In some example embodiments, the first motor cooling line LINE_MT1 may be connected to the first multi-way valve 7300, the second motor cooling line LINE_MT2, and the second storage device cooling line LINE_SD2. In some example embodiments, the second motor cooling line LINE_MT2 and the third motor cooling line LINE_MT3 may be connected to each other through (for example, by) the inverter 4000. In some example embodiments, the third motor cooling line LINE_MT3 and the fourth motor cooling line LINE_MT4 may be connected to each other through (for example, by) the motor 3000. In some example embodiments, the fourth motor cooling line LINE_MT4 may be connected to the second multi-way valve 7400. In some example embodiments, the coolant flowing from the first motor cooling line LINE_MT1 to the fourth motor cooling line LINE_MT4 may absorb heat from the motor 3000 and the inverter 4000.

In some example embodiments, the cooling lines of (for example, connected to) the radiator 7200 may include the first radiator cooling line LINE_RD1, the second radiator cooling line LINE_RD2, and a third radiator cooling line LINE_RD3.

In some example embodiments, the first radiator cooling line LINE_RD1 may be connected to the second multi-way valve 7400, the second automotive storage device heating line LINE_H_SD2, and the second radiator cooling line LINE_RD2. The second radiator cooling line LINE_RD2 and the third radiator cooling line LINE_RD3 may be connected to each other through (for example, by) the radiator 7200. The third radiator cooling line LINE_RD3 may be connected to the first multi-way valve 7300. In some example embodiments, the radiator 7300 may cool the coolant flowing from the second radiator cooling line LINE_RD2 to the third radiator cooling line LINE_RD3.

In some example embodiments, the first multi-way valve 7300 may be connected to the second battery pack cooling line LINE_BTT2, the first chiller cooling line LINE_CH1, the second chiller cooling line LINE_CH2, the first motor cooling line LINE_MT1, the first automotive storage device cooling line LINE_SD1, and the third radiator cooling line LINE_RD3.

In some example embodiments, the first multi-way valve 7300 may connect the second battery pack cooling line LINE_BTT2 to the first motor cooling line LINE_MT1 and the third radiator cooling line LINE_RD3 to the first chiller cooling line LINE_CH1. In some example embodiments, the first multi-way valve 7300 may connect the second battery pack cooling line LINE_BTT2 to the first chiller cooling line LINE_CH1, and the third radiator cooling line LINE_RD3 to the first automotive storage device cooling line LINE_SD1. In some example embodiments, the first multi-way valve 7300 may connect the second chiller cooling line LINE_CH2 to the third radiator cooling line LINE_RD3 and the first automotive storage device cooling line LINE_SD1.

In some example embodiments, the second multi-way valve 7400 may be connected to the fourth motor cooling line LINE_MT4, the first automotive storage device heating line LINE_H_SD1, and the first radiator cooling line LINE_RD1.

In some example embodiments, the second multi-way valve 7400 may connect the fourth motor cooling line LINE_MT4 to the first automotive storage device heating line LINE_H_SD1. In some example embodiments, the second multi-way valve 7400 may connect the fourth motor cooling line LINE_MT4 to the first radiator cooling line LINE_RD1.

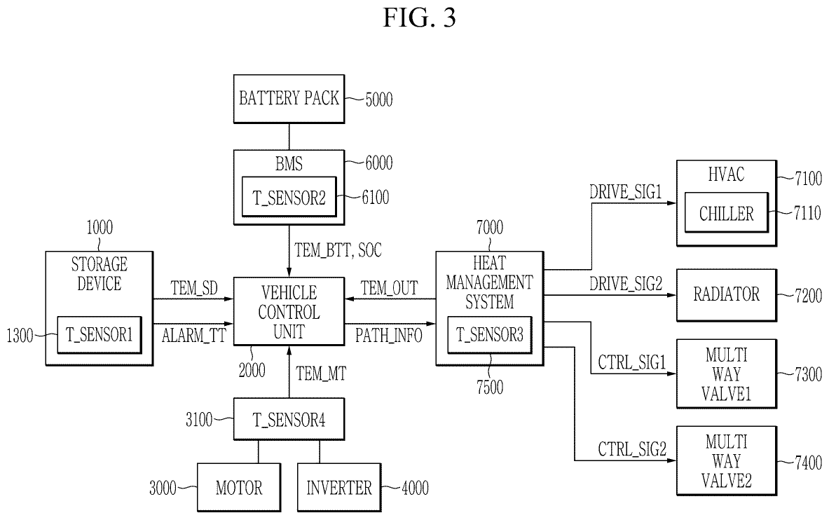

FIG. 3 is a view for explaining the vehicle control unit and the heat management system for controlling the temperature of the vehicle according to some example embodiments.

Referring to FIG. 3, the automotive storage device 1000 may include a first temperature sensor 1300. In some example embodiments, the first temperature sensor 1300 may measure an internal temperature of the automotive storage device 1000. The first temperature sensor 1300 may provide automotive storage device temperature information TEM_SD to the vehicle control unit 2000.

In some example embodiments, the battery management system 6000 may include a second temperature sensor 6100. In some example embodiments, the second temperature sensor 6100 may measure the temperature of the battery pack 5000. The second temperature sensor 6100 may battery pack temperature information TEM_BTT to the vehicle control unit. In some example embodiments, the battery management system 6000 may provide the state of charge (SOC) information of the battery pack to the vehicle control unit.

In some example embodiments, the heat management system 7000 may include a third temperature sensor 7500. In some example embodiments, the third temperature sensor 7500 may measure the external temperature of the vehicle 10. The third temperature sensor 7500 may provide the external temperature information TEM_OUT of the vehicle to the vehicle control unit 2000.

In some example embodiments, a fourth temperature sensor 3100 may measure the temperature of the motor 3000 and/or the inverter 4000. The fourth temperature sensor 3100 may provide temperature information TEM_MT of the motor and/or the inverter to the vehicle control unit 2000.

In some example embodiments, the vehicle control unit 2000 may determine the temperature of the vehicle 10 based on the automotive storage device temperature information TEM_SD, the battery pack temperature information TEM_BTT, the external temperature information TEM_OUT of the vehicle, the temperature information TEM_MT of the motor and/or the inverter, received from the first to fourth temperature sensors 1300, 6100, 7500, and 3100. In some example embodiments, the vehicle control unit 2000 may determine one of the temperature of the automotive storage device 1000, the temperature of the battery pack 5000, the external temperature of the vehicle 10, the temperature of the motor 3000 or the inverter 4000 as the temperature of the vehicle 10.

In some example embodiments, the vehicle control unit 2000 may generate path information PATH_INFO including information on the cooling lines to be connected to each other among the cooling lines connected to the first multi-way valve 7300 and information on the cooling lines to be connected to each other among the heating lines and the cooling lines, connected to the second multi-way valve 7400, based on a result of comparing the temperature of the vehicle 10 with a threshold temperature. In some example embodiments, the vehicle control unit 2000 may provide the path information PATH_INFO to the heat management system 7000.

In some example embodiments, the vehicle control unit 2000 may generate first path information if the temperature of the vehicle 10 is lower than a first threshold temperature. In some example embodiments, the first path information may be information to connect the second battery pack cooling line LINE_BTT2 to the first motor cooling line LINE_MT1, the third radiator cooling line LINE_RD3 to the first chiller cooling line LINE_CH1, and/or the fourth motor cooling line LINE_MT4 to the first automotive storage device heating line LINE_H_SD1.

In some example embodiments, the vehicle control unit 2000 may generate second path information if the temperature of the vehicle 10 is higher than the first threshold temperature and lower than a second threshold temperature. In some example embodiments, the second path information may be information to connect the second battery pack cooling line LINE_BTT2 to the first automotive storage device cooling line LINE_SD1, the third radiator cooling line LINE_RD3 to the first chiller cooling line LINE_CH1, and/or the fourth motor cooling line LINE_MT4 to the first radiator cooling line LINE_RD1. In some example embodiments, the second threshold temperature may be higher than the first threshold temperature.

In some example embodiments, the vehicle control unit 2000 may generate third path information if the temperature of the vehicle 10 is higher than the second threshold temperature and lower than a third threshold temperature. In some example embodiments, the third path information may be information to connect the second battery pack cooling line LINE_BTT2 to the first chiller cooling line LINE_CH1, the third radiator cooling line LINE_RD3 to the first automotive storage device cooling line LINE_SD1, and/or the fourth motor cooling line LINE_MT4 to the first radiator cooling line LINE_RD1. In some example embodiments, the third threshold temperature may be higher than the second threshold temperature.

In some example embodiments, the vehicle control unit 2000 may set fourth path information if the temperature of the vehicle 10 is higher than the third threshold temperature. In some example embodiments, the fourth path information may be information to connect the second battery pack cooling line LINE_BTT2 to the first chiller cooling line LINE_CH1, the third radiator cooling line LINE_RD3 and the first automotive storage device cooling line LINE_SD1 to the second chiller cooling line LINE_CH2, and/or the fourth motor cooling line LINE_MT4 to the first radiator cooling line LINE_RD1.

In some example embodiments, the vehicle control unit 2000 may determine the temperature of the automotive storage device 1000 as the temperature of the vehicle 10 and generate the fourth path information if the temperature of the automotive storage device 1000 that is received from the first temperature sensor 1300 is higher than the third threshold temperature.

In some example embodiments, the automotive storage device 1000 may enter a throttling mode if the temperature of the automotive storage device 1000 is higher than the third threshold temperature. The throttling mode may be a mode for limiting performance of the automotive storage device 1000.

In some example embodiments, the automotive storage device 1000 may provide an alarm signal ALARM_TT to the vehicle control unit 2000 to indicate that the automotive storage device 1000 enters the throttling mode if the temperature of the automotive storage device 1000 is higher than the third threshold temperature. In some example embodiments, the vehicle control unit 2000 may generate the fourth path information in response to the alarm signal ALARM_TT, and provide the fourth path information to the heat management system 7000.

In some example embodiments, the vehicle control unit 2000 may determine the temperature of the motor 3000 and/or the inverter 4000 as the temperature of the vehicle 10 and generate fourth path information if the temperature of the motor 3000 or the inverter 4000 that is received from the fourth temperature sensor 3100 is higher than a fourth threshold temperature. In some example embodiments, overheating may occur in the motor 3000 and/or the inverter 4000 if the temperature of the motor 3000 and/or the inverter 4000 is higher than the fourth threshold temperature. In some example embodiments, the fourth threshold temperature may be higher than the third threshold temperature.

In some example embodiments, the heat management system 7000 may control the HVAC system 7100, the radiator 7200, the first multi-way valve 7300, and the second multi-way valve 7400 based on the path information PATH_INFO received from the vehicle control unit 2000.

In some example embodiments, the heat management system 7000 may provide a first drive signal DRIVE_SIG1 to the HVAC system 7100 to drive the chiller 7110 based on the path information PATH_INFO. In some example embodiments, the heat management system 7000 may provide a second drive signal DRIVE_SIG2 to the radiator 7200 to drive the radiator 7200 based on the path information PATH_INFO.

In some example embodiments, the heat management system 7000 may provide a first control signal CTRL_SIG1 to the first multi-way valve 7300 based on the path information PATH_INFO for (for example, with respect to) connecting some (for example, two or more) cooling lines among the second battery pack cooling line LINE_BTT2, the first chiller cooling line LINE_CH1, the second chiller cooling line LINE_CH2, the first motor cooling line LINE_MT1, the first automotive storage device cooling line LINE_SD1, and the third radiator cooling line LINE_RD3.

In some example embodiments, the heat management system 7000 may provide a second control signal CTRL_SIG2 to the second multi-way valve 7400 based on the path information PATH_INFO for (for example, with respect to) connecting the fourth motor cooling line LINE_MT4 to the first automotive storage device heating line LINE_H_SD1 or the first radiator cooling line LINE_RD1 t.

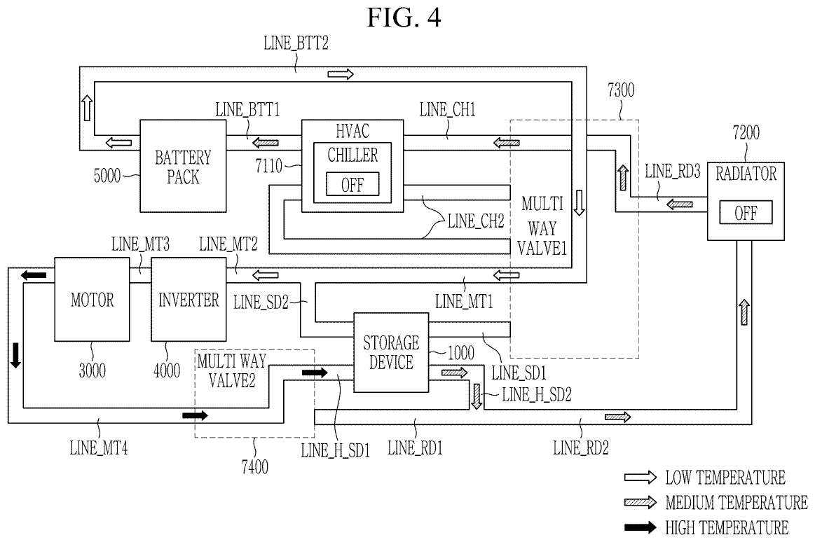

FIG. 4 is a view for explaining the vehicle system for controlling the first multi-way valve and the second multi-way valve based on the temperature of the vehicle that is lower than the first threshold temperature according to some example embodiments.

Referring to FIG. 4, a white arrow indicates that the coolant flowing through the cooling lines and/or the heating lines has a relatively low temperature, a hatched arrow indicates that the coolant has a relatively medium temperature, and a black arrow indicates that the coolant has a relatively high temperature. In some example embodiments, the low-temperature coolant may indicate the coolant having a lower temperature than the medium-temperature coolant. In some example embodiments, the medium-temperature coolant may indicate that the coolant has a lower temperature than the high-temperature coolant. In some example embodiments, the high-temperature coolant may indicate that the coolant has a higher temperature than the low-temperature coolant and the medium-temperature coolant.

In some example embodiments, the vehicle control unit 2000 may generate the first path information and provide the first path information to the heat management system 7000 if the temperature of the vehicle 10 is lower than the first threshold temperature. The heat management system 7000 may control the HVAC system 7100, the radiator 7200, the first multi-way valve 7300, and the second multi-way valve 7400, based on the first path information. In some example embodiments, the temperature of the vehicle 10 may correspond to the external temperature of the vehicle 10, the temperature of the battery pack 5000, or the temperature of the automotive storage device 1000.

In some example embodiments, the heat management system 7000 may control the first multi-way valve 7300 for (for example, with respect to) the second battery pack cooling line LINE_BTT2 to be connected to the first motor cooling line LINE_MT1, and/or the third radiator cooling line LINE_RD3 to be connected to the first chiller cooling line LINE_CH1 if the temperature of the vehicle 10 is lower than the first threshold temperature.

In some example embodiments, the heat management system 7000 may control the second multi-way valve 7400 for (for example, with respect to) the fourth motor cooling line LINE_MT4 to be connected to the first automotive storage device heating line LINE_H_SD1 if the temperature of the vehicle 10 is lower than the first threshold temperature.

In some example embodiments, the heat management system 7000 may control the first multi-way valve 7300 and the second multi-way valve 7400 for the coolant to circulated in the order of the first motor cooling line LINE_MT1, the second motor cooling line LINE_MT2, the third motor cooling line LINE_MT3, the fourth motor cooling line LINE_MT4, the first automotive storage device heating line LINE_H_SD1, the second automotive storage device heating line LINE_H_SD2, the second radiator cooling line LINE_RD2, the third radiator cooling line LINE_RD3, the first chiller cooling line LINE_CH1, the first battery pack cooling line LINE_BTT1, the second battery pack cooling line LINE_BTT2, and the first motor cooling line LINE_MT1 if the temperature of the vehicle 10 is lower than the first threshold temperature.

In some example embodiments, the coolant flowing through the first motor cooling line LINE_MT1 and the second motor cooling line LINE_MT2 may have relatively low temperature. In some example embodiments, the coolant flowing from the second motor cooling line LINE_MT2 to the fourth motor cooling line LINE_MT4 may have a temperature increased from the low temperature to the relatively high temperature as the coolant absorbs heat from the motor 3000 and the inverter 4000. In some example embodiments, the coolant flowing through the fourth motor cooling line LINE_MT4 and the first automotive storage device heating line LINE_H_SD1 may have the relatively high temperature.

In some example embodiments, the coolant flowing from the first automotive storage device heating line LINE_H_SD1 to the second automotive storage device heating line LINE_H_SD2 may have a temperature decreased from the high temperature to the medium temperature as the coolant releases heat to the automotive storage device 1000. In some example embodiments, the temperature of the automotive storage device 1000 may be increased when the coolant releases heat. In some example embodiments, the coolant flowing through the second automotive storage device heating line LINE_H_SD2 and the second radiator cooling line LINE_RD2 may have the medium temperature.

In some example embodiments, the radiator 7200 and the chiller 7110 may not be driven (OFF) if the temperature of the vehicle 10 is lower than the first threshold temperature. In some example embodiments, the coolant flowing through the third radiator cooling line LINE_RD3, the first chiller cooling line LINE_CH1, and the first battery pack cooling line LINE_BTT1 may have the medium temperature.

In some example embodiments, the coolant flowing from the first battery pack cooling line LINE_BTT1 to the second battery pack cooling line LINE_BTT2 may have a temperature decreased from the medium temperature to the low temperature as the coolant releases heat to the battery pack 5000. In some example embodiments, the temperature of the battery pack 5000 may be increased when the coolant releases heat. In some example embodiments, the coolant flowing through the second battery pack cooling line LINE_BTT2 and the first motor cooling line LINE_MT1 may have the relatively low temperature.

In some example embodiments, error bits of the data stored in the automotive storage device 1000 may be increased if the temperature of the vehicle 10 is lower than the first threshold temperature. In some example embodiments, output of the battery pack 5000 may be reduced or a charge capacity of the battery pack 5000 may be reduced if the temperature of the vehicle 10 is lower than the first threshold temperature.

In some example embodiments, the heat management system 7000 may control the first multi-way valve 7300 and the second multi-way valve 7400 to transfer heat from the motor 3000 and the inverter 4000 to the automotive storage device 1000 and the battery pack 5000 through the cooling lines and the heating lines if the temperature of the vehicle 10 is lower than the first threshold temperature, thereby increasing the temperatures of the automotive storage device 1000 and the battery pack 5000.

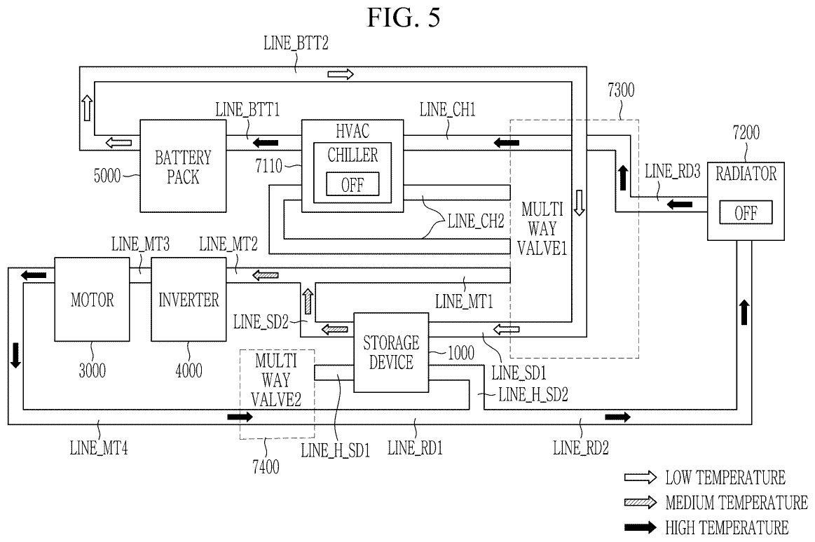

FIG. 5 is a view for explaining the vehicle system for controlling the first multi-way valve and the second multi-way valve based on the temperature of the vehicle that is higher than the first threshold temperature and lower than the second threshold temperature according to some example embodiments.

Referring to FIG. 5, the white arrow indicates that the coolant flowing through the cooling lines and the heating lines has the low temperature, the hatched arrow indicates that the coolant has the medium temperature, and the black arrow indicates that the coolant has the high temperature.

In some example embodiments, the vehicle control unit 2000 may generate the second path information and provide the second path information to the heat management system 7000 if the temperature of the vehicle 10 is higher than the first threshold temperature and, for example, lower than the second threshold temperature. The heat management system 7000 may control the HVAC system 7100, the radiator 7200, the first multi-way valve 7300, and the second multi-way valve 7400, based on the second path information. In some example embodiments, the temperature of the vehicle 10 may correspond to the temperature of the battery pack 5000, or the temperature of the automotive storage device 1000.

In some example embodiments, the heat management system 7000 may control the first multi-way valve 7300 for the second battery pack cooling line LINE_BTT2 to be connected to the first automotive storage device cooling line LINE_SD1, and the third radiator cooling line LINE_RD3 to be connected to the first chiller cooling line LINE_CH1 if the temperature of the vehicle 10 is higher than the first threshold temperature and lower than the second threshold temperature.

In some example embodiments, the heat management system 7000 may control the second multi-way valve 7400 for the fourth motor cooling line LINE_MT4 to be connected to the first radiator cooling line LINE_RD1 if the temperature of the vehicle 10 is higher than the first threshold temperature and lower than the second threshold temperature.

In some example embodiments, the heat management system 7000 may control the first multi-way valve 7300 and the second multi-way valve 7400 for the coolant to be circulated in the order of the first automotive storage device cooling line LINE_SD1, the second automotive storage device cooling line LINE_SD2, the second motor cooling line LINE_MT2, the third motor cooling line LINE_MT3, the fourth motor cooling line LINE_MT4, the first radiator cooling line LINE_RD1, the second radiator cooling line LINE_RD2, the third radiator cooling line LINE_RD3, the first chiller cooling line LINE_CH1, the first battery pack cooling line LINE_BTT1, the second battery pack cooling line LINE_BTT2, and the first automotive storage device cooling line LINE_SD1 if the temperature of the vehicle 10 is higher than the first threshold temperature and, for example, lower than the second threshold temperature.

In some example embodiments, the coolant flowing through the first automotive storage device cooling line LINE_SD1 may have the low temperature. In some example embodiments, the coolant flowing from the first automotive storage device cooling line LINE_SD1 to the second automotive storage device cooling line LINE_SD2 may have a temperature increased from the low temperature to the medium temperature as the coolant absorbs heat from the automotive storage device 1000. In some example embodiments, the temperature of the automotive storage device 1000 may be decreased when the coolant absorbs heat from the automotive storage device 1000.

In some example embodiments, the coolant flowing to the second automotive storage device cooling line LINE_SD2 and the second motor cooling line LINE_MT2 may have the medium temperature.

In some example embodiments, the coolant flowing from the second motor cooling line LINE_MT2 to the fourth motor cooling line LINE_MT4 may have a temperature increased from the medium temperature to the high temperature as the coolant absorbs heat from the motor 3000 and the inverter 4000. In some example embodiments, the coolant flowing through the fourth motor cooling line LINE_MT4, the first radiator cooling line LINE_RD1, and the second radiator cooling line LINE_RD2 may have the relatively high temperature.

In some example embodiments, the radiator 7200 and the chiller 7110 may not be driven (OFF) if the temperature of the vehicle 10 is higher than the first threshold temperature and lower than the second threshold temperature. In some example embodiments, the coolant flowing through the third radiator cooling line LINE_RD3, the first chiller cooling line LINE_CH1, and the first battery pack cooling line LINE_BTT1 may have the high temperature.

In some example embodiments, the coolant flowing from the first battery pack cooling line LINE_BTT1 to the second battery pack cooling line LINE_BTT2 may have the temperature decreased from the high temperature to the medium temperature as the coolant releases heat to the battery pack 5000. In some example embodiments, the temperature of the battery pack 5000 may be increased when the coolant releases heat to the battery pack 5000. In some example embodiments, the coolant flowing through the second battery pack cooling line LINE_BTT2 and the first automotive storage device cooling line LINE_SD1 may have the low temperature.

In some example embodiments, the heat management system 7000 may control the first multi-way valve 7300 and the second multi-way valve 7400 to transfer heat of the automotive storage device 1000, heat of the motor 3000, and heat of the inverter 4000 to the battery pack 5000 through the cooling lines if the temperature of the vehicle 10 is higher than the first threshold temperature and lower than the second threshold temperature, thereby decreasing the temperature of the automotive storage device 1000 and increasing the temperature of the battery pack 5000.

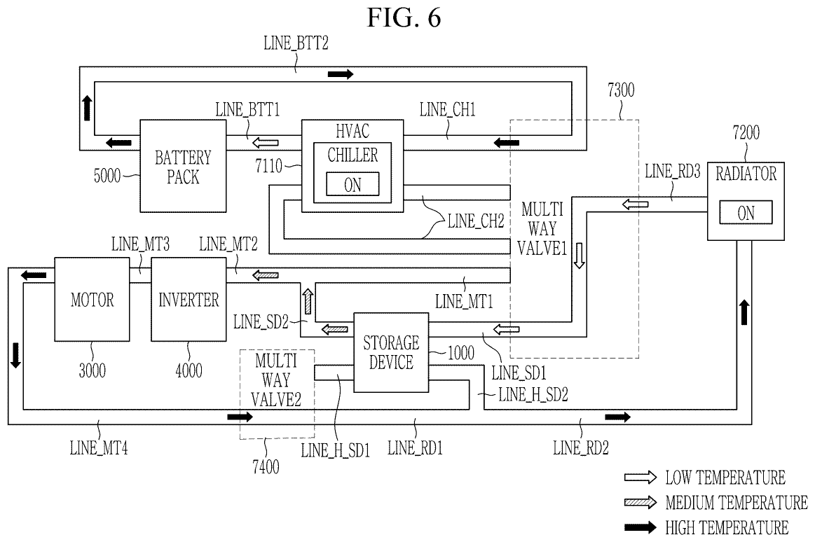

FIG. 6 is a view for explaining the vehicle system for controlling the first multi-way valve and the second multi-way valve based on the temperature of the vehicle that is higher than the second threshold temperature and lower than the third threshold temperature according to some example embodiments.

Referring to FIG. 6, the white arrow indicates that the coolant flowing through the cooling lines and the heating lines has the low temperature, the hatched arrow indicates that the coolant has the medium temperature, and the black arrow indicates that the coolant has the high temperature.

In some example embodiments, the vehicle control unit 2000 may generate the third path information and provide the third path information to the heat management system 7000 if the temperature of the vehicle 10 is higher than the second threshold temperature and lower than the third threshold temperature. The heat management system 7000 may control the HVAC system 7100, the radiator 7200, the first multi-way valve 7300, and the second multi-way valve 7400, based on the third path information. In some example embodiments, the temperature of the vehicle 10 may correspond to the temperature of the battery pack 5000, or the temperature of the automotive storage device 1000.

In some example embodiments, the heat management system 7000 may control the first multi-way valve 7300 for the second battery pack cooling line LINE_BTT2 to be connected to the first chiller cooling line LINE_CH1, and the third radiator cooling line LINE_RD3 to be connected to the first automotive storage device cooling line LINE_SD1 if the temperature of the vehicle 10 is higher than the second threshold temperature and lower than the third threshold temperature.

In some example embodiments, the heat management system 7000 may control the second multi-way valve 7400 for the fourth motor cooling line LINE_MT4 to be connected to the first radiator cooling line LINE_RD1 if the temperature of the vehicle 10 is higher than the second threshold temperature and lower than the third threshold temperature.

In some example embodiments, the heat management system 7000 may control the first multi-way valve 7300 for the coolant to be circulated in the order of the first battery pack cooling line LINE_BTT1, the second battery pack cooling line LINE_BTT2, the first chiller cooling line LINE_CH1, and the first battery pack cooling line LINE_BTT1 if the temperature of the vehicle 10 is higher than the second threshold temperature and lower than the third threshold temperature.

In some example embodiments, the coolant flowing from the first battery pack cooling line LINE_BTT1 to the second battery pack cooling line LINE_BTT2 may have the temperature increased from the low temperature to the high temperature as the coolant absorbs heat from the battery pack 5000. In some example embodiments, the temperature of the battery pack 5000 may be decreased when the coolant absorbs heat from the battery pack 5000.

In some example embodiments, the coolant flowing through the second battery pack cooling line LINE_BTT2 and the first chiller cooling line LINE_CH1 may have the high temperature.

In some example embodiments, the heat management system 7000 may drive the chiller 7110 (ON) if the temperature of the vehicle 10 is higher than the second threshold temperature and lower than the third threshold temperature. In some example embodiments, the coolant flowing from the first chiller cooling line LINE_CH1 to the first battery pack cooling line LINE_BTT1 may have a temperature decreased from the high temperature to the low temperature as the chiller 7110 absorbs heat from the coolant. The coolant flowing to the first battery pack cooling line LINE_BTT1 may have the low temperature.

In some example embodiments, the heat management system 7000 may control the first multi-way valve 7300 to transfer heat from the battery pack 5000 to the chiller 7110 through the cooling lines if the temperature of the vehicle 10 is higher than the second threshold temperature and lower than the third threshold temperature, thereby decreasing the temperature of the battery pack 5000.

In some example embodiments, the heat management system 7000 may control the first multi-way valve 7300 and the second multi-way valve 7400 for the coolant to be circulated in the order of the first automotive storage device cooling line LINE_SD1, the second automotive storage device cooling line LINE_SD2, the second motor cooling line LINE_MT2, the third motor cooling line LINE_MT3, the fourth motor cooling line LINE_MT4, the first radiator cooling line LINE_RD1, the second radiator cooling line LINE_RD2, the third radiator cooling line LINE_RD3, and the first automotive storage device cooling line LINE_SD1 if the temperature of the vehicle 10 is higher than the second threshold temperature and lower than the third threshold temperature.

In some example embodiments, the coolant flowing from the first automotive storage device cooling line LINE_SD1 to the second automotive storage device cooling line LINE_SD2 may have the temperature increased from the low temperature to the medium temperature as the coolant absorbs heat from the automotive storage device 1000. In some example embodiments, the temperature of the automotive storage device 1000 may be decreased when the coolant absorbs heat from the automotive storage device 1000. In some example embodiments, the coolant flowing through the second automotive storage device cooling line LINE_SD2 and the second motor cooling line LINE_MT2 may have the medium temperature.

In some example embodiments, the coolant flowing from the second motor cooling line LINE_MT2 to the fourth motor cooling line LINE_MT4 may have the temperature increased from the medium temperature to the high temperature as the coolant absorbs heat from the motor 3000 and the inverter 4000. In some example embodiments, the coolant flowing through the fourth motor cooling line LINE_MT4, the first radiator cooling line LINE_RD1, and the second radiator cooling line LINE_RD2 may have the high temperature.

In some example embodiments, the heat management system 7000 may drive the radiator 7200 (ON) if the temperature of the vehicle 10 is higher than the second threshold temperature and lower than the third threshold temperature. In some example embodiments, the coolant flowing from the second radiator cooling line LINE_RD2 to the third radiator cooling line LINE_RD3 may have the temperature decreased from the high temperature to the low temperature as the radiator 7200 absorbs heat from the coolant. In some example embodiments, the coolant flowing through the third radiator cooling line LINE_RD3 and the first automotive storage device cooling line LINE_SD1 may have the low temperature.

In some example embodiments, the heat management system 7000 may control the first multi-way valve 7300 and the second multi-way valve 7400 to transfer heat of the automotive storage device 1000, heat of the motor 3000, and heat of the inverter 4000 to the radiator 7200 through the cooling lines if the temperature of the vehicle 10 is higher than the second threshold temperature and lower than the third threshold temperature, thereby decreasing the temperature of the automotive storage device 1000, the temperature of the motor 3000, and the temperature of the inverter 4000.

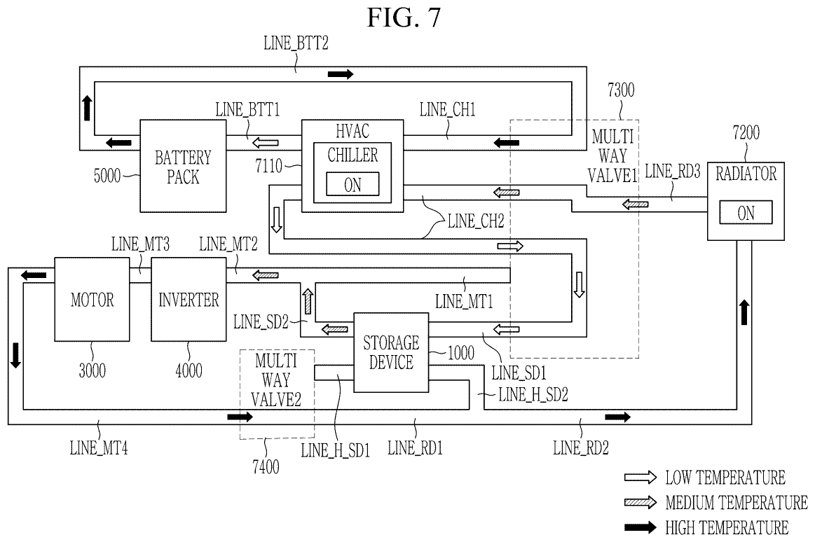

FIG. 7 is a view for explaining the vehicle system for controlling the first multi-way valve and the second multi-way valve based on the temperature of the vehicle that is higher than the third threshold temperature according to some example embodiments.

Referring to FIG. 7, the white arrow indicates that the coolant flowing through the cooling lines and the heating lines has the low temperature, the hatched arrow indicates that the coolant has the medium temperature, and the black arrow indicates that the coolant has the high temperature.

In some example embodiments, the vehicle control unit 2000 may generate the fourth path information and provide the fourth path information to the heat management system 7000 if the temperature of the vehicle 10 is higher than the third threshold temperature. In some example embodiments, the third threshold temperature may correspond to the temperature at which the automotive storage device is operated in the throttling mode. In some example embodiments, the temperature of the vehicle 10 may correspond to the temperature of the automotive storage device 1000, the temperature of the motor 3000 or the inverter 4000.

In some example embodiments, the vehicle control unit 2000 may generate the fourth path information and provide the fourth path information to the heat management system 7000 when the alarm signal indicating the entry of the throttling mode is received from the automotive storage device 1000.

In some example embodiments, the vehicle control unit 2000 may generate the fourth path information and provide the fourth path information to the heat management system 7000 if the temperature of the vehicle 10 is higher than the fourth threshold temperature. In some example embodiments, the fourth threshold temperature may correspond to a temperature at which overheating of the motor and the inverter occurs.

In some example embodiments, the heat management system 7000 may control the HVAC system 7100, the radiator 7200, the first multi-way valve 7300, and the second multi-way valve 7400, based on the fourth path information.

In some example embodiments, the heat management system 7000 may control the first multi-way valve 7300 for the second battery pack cooling line LINE_BTT2 to be connected to the first chiller cooling line LINE_CH1, and the third radiator cooling line LINE_RD3 and the first automotive storage device cooling line LINE_SD1 to be connected to the second chiller cooling line LINE_CH2 if the temperature of the vehicle 10 is higher than the third threshold temperature or the fourth threshold temperature.

In some example embodiments, the heat management system 7000 may control the second multi-way valve 7400 for the fourth motor cooling line LINE_MT4 to be connected to the first radiator cooling line LINE_RD1 if the temperature of the vehicle 10 is higher than the third threshold temperature or the fourth threshold temperature.

In some example embodiments, the heat management system 7000 may control the first multi-way valve 7300 for the coolant to be circulated in the order of the first battery pack cooling line LINE_BTT1, the second battery pack cooling line LINE_BTT2, the first chiller cooling line LINE_CH1, and the first battery pack cooling line LINE_BTT1 if the temperature of the vehicle 10 is higher than the third threshold temperature or the fourth threshold temperature.

In some example embodiments, the heat management system 7000 may control the first multi-way valve 7300 to drive the chiller 7110 and transfer heat from the battery pack 5000 to the chiller 7110 through the cooling lines if the temperature of the vehicle 10 is higher than the third threshold temperature or the fourth threshold temperature.

In some example embodiments, the heat management system 7000 may control the first multi-way valve 7300 and the second multi-way valve 7400 for the coolant to be circulated in the order of the first automotive storage device cooling line LINE_SD1, the second automotive storage device cooling line LINE_SD2, the second motor cooling line LINE_MT2, the third motor cooling line LINE_MT3, the fourth motor cooling line LINE_MT4, the first radiator cooling line LINE_RD1, the second radiator cooling line LINE_RD2, the third radiator cooling line LINE_RD3, the second chiller cooling line LINE_CH2, and the first automotive storage device cooling line LINE_SD1 if the temperature of the vehicle 10 is higher than the third threshold temperature or the fourth threshold temperature.

In some example embodiments, the coolant flowing from the first automotive storage device cooling line LINE_SD1 to the second automotive storage device cooling line LINE_SD2 may have the temperature increased from the low temperature to the medium temperature as the coolant absorbs heat from the automotive storage device. In some example embodiments, the temperature of the automotive storage device 1000 may be decreased when the coolant absorbs heat from the automotive storage device 1000. In some example embodiments, the coolant flowing through the second automotive storage device cooling line LINE_SD2 and the second motor cooling line LINE_MT2 may have the medium temperature.

In some example embodiments, the coolant flowing from the second motor cooling line LINE_MT2 to the fourth motor cooling line LINE_MT4 may have the temperature increased from the medium temperature to the high temperature as the coolant absorbs heat from the motor 3000 and the inverter 4000.

In some example embodiments, the coolant flowing through the fourth motor cooling line LINE_MT4, the first radiator cooling line LINE_RD1, and the second radiator cooling line LINE_RD2 may have the high temperature.

In some example embodiments, the heat management system 7000 may drive the radiator 7200 and absorb heat from the coolant flowing from the second radiator cooling line LINE_RD2 to the third radiator cooling line LINE_RD3 if the temperature of the vehicle 10 is higher than the third threshold temperature or the fourth threshold temperature. The coolant flowing from the second radiator cooling line LINE_RD2 to the third radiator cooling line LINE_RD3 may have the temperature decreased from the high temperature to the low temperature.

In some example embodiments, the coolant flowing from the third radiator cooling line LINE_RD3 to the second chiller cooling line LINE_CH2 may have the temperature decreased from the medium temperature to the low temperature as the chiller 7110 absorbs heat from the coolant. The coolant flowing from the second chiller cooling line LINE_CH2 to the first automotive storage device cooling line LINE_SD1 may have the low temperature.

In some example embodiments, the heat management system 7000 may control the first multi-way valve 7300 and the second multi-way valve 7400 to transfer heat of the automotive storage device 1000, heat of the motor 3000, and heat of the inverter 4000 not only to the radiator 7200 but also to the chiller 7110 through the cooling lines if the temperature of the vehicle 10 is higher than the third threshold temperature or the fourth threshold temperature, thereby further decreasing the temperature of the automotive storage device 1000, the temperature of the motor 3000, and the inverter 4000 than a case where heat of the automotive storage device 1000, heat of the motor 3000, and heat of the inverter 4000 are transferred only to the radiator 7200 through the cooling lines.

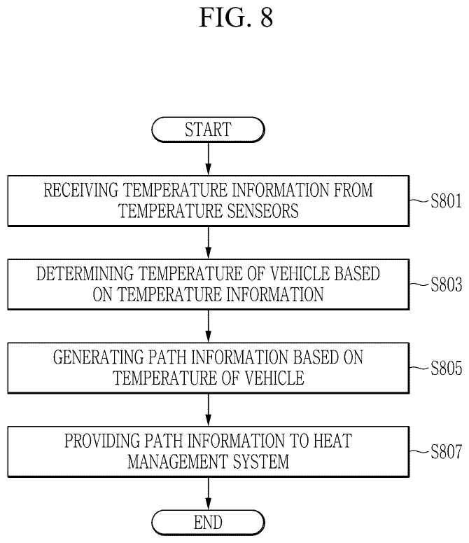

FIG. 8 is a flowchart illustrating the vehicle system for generating path information according to some example embodiments.

Referring to FIG. 8, in S801, the vehicle control unit 2000 may receive temperature information from the temperature sensors. In some example embodiments, the vehicle control unit 2000 may receive the temperature information of the automotive storage device 1000 from the first temperature sensor 1300, receive the temperature information of the battery pack 5000 from the second temperature sensor 6100, receive the external temperature information of the vehicle from the third temperature sensor 7500, and receive the temperature information of the motor 3000 and/or the inverter 4000 from the fourth temperature sensor 3100.

In S803, the vehicle control unit 2000 may determine the temperature of the vehicle 10 based on the temperature information. In some example embodiments, the vehicle control unit 2000 may determine one of the temperature of the automotive storage device 1000, the temperature of the battery pack 5000, the external temperature of the vehicle 10, the temperature of the motor 3000 as the temperature of the vehicle 10. In some example embodiments, the vehicle control unit 2000 may determine the external temperature of the vehicle as the temperature of the vehicle 10 if the external temperature of the vehicle is lower than the first threshold temperature. In some example embodiments, the vehicle control unit 2000 may determine the temperature of the battery pack 5000 or the temperature of the automotive storage device 1000 as the temperature of the vehicle 10 if the temperature of the battery pack 5000 or the temperature of the automotive storage device 1000 is higher than the first threshold temperature and lower than the second threshold temperature. In some example embodiments, the vehicle control unit 2000 may determine the temperature of the battery pack 5000 or the temperature of the automotive storage device 1000 as the temperature of the vehicle 10 if the temperature of the battery pack 5000 or the temperature of the automotive storage device 1000 is higher than the second threshold temperature and lower than the third threshold temperature. In some example embodiments, the vehicle control unit 2000 may determine the temperature of the automotive storage device 1000 as the temperature of the vehicle 10 if the temperature of the automotive storage device 1000 is higher than the third threshold temperature. In some example embodiments, the vehicle control unit may determine the temperature of the motor 3000 or the inverter 4000 as the temperature of the vehicle 10 if the temperature of the motor 3000 or the inverter 4000 is higher than the fourth threshold temperature, which is higher than the third threshold temperature.

In S805, the vehicle control unit 2000 may generate the path information based on the temperature of the vehicle 10. In some example embodiments, the vehicle control unit 2000 may generate the first path information if the temperature of the vehicle 10 is lower than the first threshold temperature. In some example embodiments, the vehicle control unit 2000 may generate the second path information if the temperature of the vehicle 10 is higher than the first threshold temperature and lower than the second threshold temperature. In some example embodiments, the vehicle control unit 2000 may generate the third path information if the temperature of the vehicle 10 is higher than the second threshold temperature and lower than the third threshold temperature. In some example embodiments, the vehicle control unit 2000 may generate the fourth path information if the temperature of the vehicle 10 is higher than the third threshold temperature.

In S807, the vehicle control unit 2000 may provide the path information to the heat management system 7000. In some example embodiments, the heat management system 7000 may control the first multi-way valve 7300 to connect some (for example, two or more) cooling lines among the battery pack cooling line 5000, the cooling line of the chiller 7110, the automotive storage device cooling line 1000, the motor cooling line 3000, and the radiator cooling line 7200 to each other based on the path information. In some example embodiments, the heat management system 7000 may control the second multi-way valve 7400 to connect the motor cooling line 3000 to the automotive storage device heating line 1000 or to the radiator cooling line 7200 based on the path information. In some example embodiments, the heat management system 7000 may control the first multi-way valve 7300 and/or the second multi-way valve 7400 to circulate the coolant flowing through the cooling lines and the heating lines based on the path information.

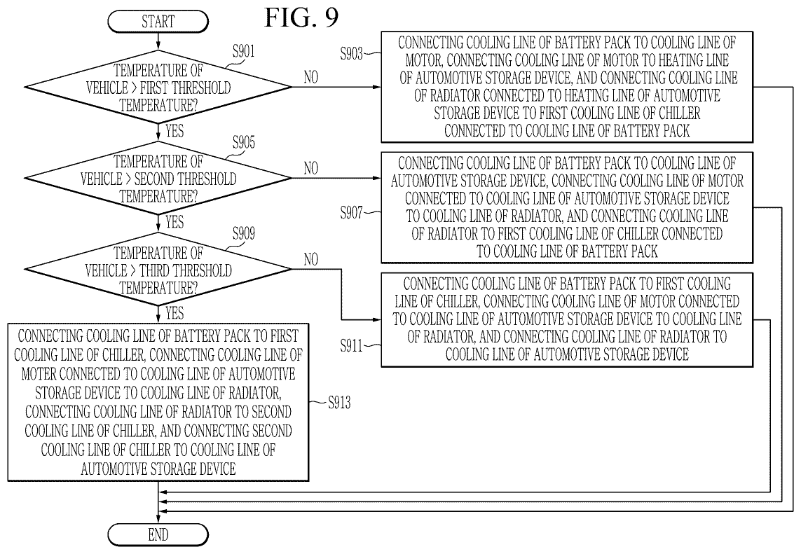

FIG. 9 is a flowchart for explaining the vehicle system for controlling the first multi-way valve and the second multi-way valve based on the temperature of the vehicle according to some example embodiments.

Referring to FIG. 9, in S901, the vehicle system 50 may compare whether the temperature of the vehicle 10 is higher than the first threshold temperature. In some example embodiments, S903 may be performed if the temperature of the vehicle 10 is lower than the first threshold temperature. In some example embodiments, S905 may be performed if the temperature of the vehicle 10 is higher than the first threshold temperature.

In S903, if the temperature of the vehicle 10 is lower than the first threshold temperature, the vehicle system 50 may connect the battery pack cooling line 5000 to the motor cooling line 3000, connect the motor cooling line 3000 to the automotive storage device heating line 1000, and connect the radiator cooling line 7200 connected to the automotive storage device heating line 1000 to the first chiller cooling line 7110 connected to the battery pack cooling line 5000. In some example embodiments, the vehicle system 50 may transfer heat of the motor 3000 and heat of the inverter 4000 to the automotive storage device 1000 and the battery pack 5000 through the cooling lines and the heating line if the temperature of the vehicle 10 is lower than the first threshold temperature.

In S905, the vehicle system 50 may compare whether the temperature of the vehicle 10 is higher than the second threshold temperature. In some example embodiments, S907 may be performed if the temperature of the vehicle 10 is higher than the first threshold temperature and lower than the second threshold temperature. In some example embodiments, S909 may be performed if the temperature of the vehicle 10 is higher than the third threshold temperature.

In S907, if the temperature of the vehicle 10 is higher than the first threshold temperature and lower than the second threshold temperature, the vehicle system 50 may connect the battery pack cooling line 5000 to the automotive storage device cooling line 1000, connect the motor cooling line 3000 connected to the automotive storage device cooling line 1000 to the radiator cooling line 7200, and the system 50 may connect the radiator cooling line 7200 to the first chiller cooling line 7110 connected to the battery pack cooling line 5000. In some example embodiments, the vehicle system 50 may transfer heat of the automotive storage device 1000, heat of the motor 3000, and heat of the inverter 4000 to the battery pack 5000 through the cooling lines if the temperature of the vehicle 10 is higher than the first threshold temperature and lower than the second threshold temperature.

In S909, the vehicle system 50 may compare whether the temperature of the vehicle 10 is higher than the third threshold temperature. In some example embodiments, S911 may be performed if the temperature of the vehicle 10 is higher than the second threshold temperature and lower than the third threshold temperature. In some example embodiments, S913 may be performed if the temperature of the vehicle 10 is higher than the third threshold temperature.

In S911, if the temperature of the vehicle 10 is higher than the second threshold temperature and lower than the third threshold temperature, the vehicle system 50 may connect the battery pack cooling line 5000 to the first chiller cooling line 7110, connect the motor cooling line 3000 connected to the automotive storage device cooling line 1000 to the radiator cooling line 7200, and connect the radiator cooling line 7200 to the automotive storage device cooling line. In some example embodiments, the vehicle system 50 may drive the chiller 7110 and the radiator 7200 if the temperature of the vehicle 10 is higher than the second threshold temperature and lower than the third threshold temperature. In some example embodiments, the vehicle system 50 may transfer heat of the automotive storage device 1000, heat of the motor 3000, and heat of the inverter 4000 to the radiator 7200 through the cooling lines, and transfer heat of the battery pack 5000 to the chiller 7110 through the cooling lines if the temperature of the vehicle 10 is higher than the second threshold temperature and lower than the third threshold temperature.

In S913, if the temperature of the vehicle 10 is higher than the third threshold temperature, the vehicle system 50 may connect the battery pack cooling line 5000 to the first chiller cooling line 7110, connect the motor cooling line 3000 connected to the automotive storage device cooling line 1000 to the radiator cooling line 7200, connect the radiator cooling line 7200 to the second chiller cooling line 7110, and connect the second chiller cooling line 7110 to the automotive storage device cooling line 1000. The vehicle system 50 may drive the chiller 7110 and the radiator 7200 if the temperature of the vehicle 10 is higher than the third threshold temperature. In some example embodiments, the vehicle system 50 may transfer heat of the automotive storage device 1000, heat of the motor 3000, and heat of the inverter 4000 to the chiller 7110 and the radiator 7200 through the cooling lines, and transfer heat of the battery pack 5000 to the chiller 7110 through the cooling lines if the temperature of the vehicle 10 is higher than the third threshold temperature.

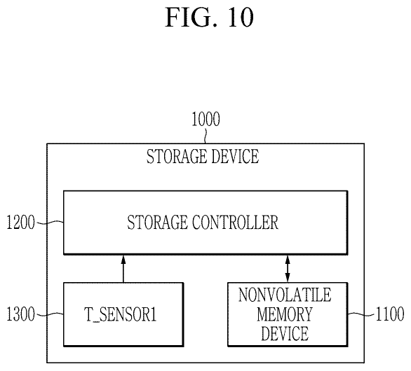

FIG. 10 is a view for explaining the automotive storage device according to some example embodiments.

Referring to FIG. 10, the automotive storage device 1000 may include a nonvolatile memory device 1100, a storage controller 1200, and the first temperature sensor 1300.

In some example embodiments, the nonvolatile memory device 1100 may store the data. The nonvolatile memory device 1100 may be operated in response to control of the storage controller 1200. In some example embodiments, the nonvolatile memory device 1100 may be a NAND flash memory. The nonvolatile memory device 1100 may include a plurality of memory blocks. The plurality of memory blocks may include a plurality of memory cells that store the data.

In some example embodiments, the nonvolatile memory device 1100 may receive a command and an address from the storage controller 1200, and perform an operation indicated by the command for a region selected by the address. The nonvolatile memory device 1100 may perform a program operation (write operation) to store the data in the region selected by the address, a read operation to read the data, or an erase operation to delete the data.

The storage controller 1200 may control overall operations of the automotive storage device 1000.

In some example embodiments, the storage controller 1200 may control the nonvolatile memory device 1100 to perform the write operation, the read operation, the erase operation, or the like. The storage controller 1200 may provide write commands, addresses, and data to the nonvolatile memory device 1100 during the write operation. The storage controller 1200 may provide read commands, addresses, and data to the nonvolatile memory device 1100 during the read operation. The storage controller 1200 may provide erase commands and addresses, to the nonvolatile memory device 1100 during the erase operation.

In some example embodiments, the first temperature sensor 1300 may measure the internal temperature of the automotive storage device 1000. In some example embodiments, the first temperature sensor 1300 may be disposed outside the storage controller 1200 and the nonvolatile memory device 1100. In some example embodiments, the first temperature sensor 1300 may be disposed in the storage controller 1200. In some example embodiments, the first temperature sensor 1300 may be disposed in the nonvolatile memory device 1100.

In some example embodiments, the automotive storage device 1000 may provide the temperature of the automotive storage device 1000 that is measured by the first temperature sensor 1300 to the vehicle control unit 2000.

In some example embodiments, the automotive storage device 1000 may enter the throttling mode if the temperature of the automotive storage device 1000 that is measured by the first temperature sensor 1300 is higher than the third threshold temperature. In some example embodiments, the throttling mode may be the mode for limiting the operational performance of the automotive storage device 1000.

In some example embodiments, the automotive storage device 1000 may provide the alarm signal to the vehicle control unit 2000 to indicate that the automotive storage device 1000 enters the throttling mode if the temperature of the automotive storage device 1000 is higher than the third threshold temperature.

In some example embodiments, the storage controller 1200 may control the operation of the automotive storage device 1000 to be in the throttling mode if the temperature of the automotive storage device 1000 is higher than the third threshold temperature. In some example embodiments, in the throttling mode, the storage controller 1200 may perform the operation to reduce the temperature of the automotive storage device 1000. In some example embodiments, in the throttling mode, the storage controller 1200 may reduce a rate at which the data is input/output into/from the nonvolatile memory device 1100. In some example embodiments, in the throttling mode, the storage controller 1200 may activate an operation of a fan attached to the automotive storage device 1000.

Although example embodiments of inventive concepts have been described in detail hereinabove, the spirit and scope of the inventive concepts are not limited thereto, and may include various modifications and alterations made by those ordinarily skilled in the art according a basic spirit of inventive concepts as in the claims.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Any or all of the elements described with reference to FIG. 10 may communicate with any or all other elements described with reference to FIG. 1. For example, any element may engage in one-way and/or two-way and/or broadcast communication with any or all other elements in FIG. 10, to transfer and/or exchange and/or receive information such as but not limited to data and/or commands, such as in a serial and/or parallel manner, via a bus such as a wireless and/or a wired bus (not illustrated). The information may be in encoded various formats, such as in an analog format and/or in a digital format.

What is claimed is:

1. A vehicle system, comprising:
a first valve configured to connect to each other two or more cooling lines among
a battery pack cooling line,
an automotive storage device cooling line,
a motor cooling line that is connected to the automotive storage device cooling line,
a radiator cooling line,
a first chiller cooling line, and
a second chiller cooling line;
a second valve configured to connect the motor cooling line to an automotive storage device heating line or to the radiator cooling line; and
a heat management system configured to control the first valve with respect to connecting the battery pack cooling line to the automotive storage device cooling line and connecting the radiator cooling line to the first chiller cooling line, the first chiller cooling line being connected to the battery pack cooling line, and is further configured to control the second valve with respect to connecting the motor cooling line to the radiator cooling line, in response to a temperature of a vehicle being higher than a first threshold temperature.

2. The system of claim 1, wherein
the first valve is configured to transfer heat of an automotive storage device and heat of a motor from the automotive storage device cooling line, the motor cooling line, and the radiator cooling line to a battery pack, the heat being transferred through the first chiller cooling line and the battery pack cooling line.

3. The system of claim 1, wherein the heat management system is configured to control the first valve with respect to connecting the battery pack cooling line to the motor cooling line and to connecting the radiator cooling line to the first chiller cooling line, and is further configured to control the second valve with respect to connecting the motor cooling line to the automotive storage device heating line, in response to the temperature of the vehicle being lower than the first threshold temperature.

4. The system of claim 3, wherein the second valve is configured to transfer heat of a motor from the motor cooling line to an automotive storage device, the heat being transferred through the automotive storage device heating line, and
the first valve is configured to transfer heat of the motor from the automotive storage device heating line to a battery pack, the heat being transferred through the radiator cooling line, the first chiller cooling line, and the battery pack cooling line.

5. The system of claim 1, wherein the heat management system is configured to drive a chiller and a radiator, to control the first valve with respect to connecting the battery pack cooling line to the first chiller cooling line and connecting the radiator cooling line to the automotive storage device cooling line, and to control the second valve with respect to connecting the motor cooling line to the radiator cooling line, in response to the temperature of the vehicle being higher than a second threshold temperature that is higher than the first threshold temperature.

6. The system of claim 5, wherein the first valve is configured to transfer heat of a battery pack from the battery pack cooling line to the chiller, the heat being transferred through the first chiller cooling line, and
the second valve is configured to transfer heat of an automotive storage device and heat of a motor from the automotive storage device cooling line and the motor cooling line to the radiator, the heat being transferred through the radiator cooling line.

7. The system of claim 1, wherein the heat management system is configured to drive a chiller and a radiator, to control the first valve with respect to connecting the battery pack cooling line to the first chiller cooling line, the radiator cooling line to the second chiller cooling line, and the second chiller cooling line to the automotive storage device cooling line, and to control the second valve with respect to connecting the motor cooling line to the radiator cooling line, in response to the temperature of the vehicle being higher than a third threshold temperature that is higher than the first threshold temperature.

8. The system of claim 7, wherein the first valve is configured to transfer heat of a battery pack from the battery pack cooling line to a chiller, the heat being transferred through the first chiller cooling line,
the second valve is configured to transfer heat of an automotive storage device and heat of the motor that from the automotive storage device cooling line and the motor cooling line to the radiator, the heat being transferred through the radiator cooling line, and
the first valve is configured to transfer heat of the automotive storage device and heat of the motor from the radiator cooling line to the chiller, the heat being transferred through the second chiller cooling line.

9. The system of claim 7, wherein the temperature of the vehicle corresponds to a temperature of the automotive storage device, and
the automotive storage device is configured to enter a throttling mode with respect to limiting performance of the automotive storage device in response to the temperature of the vehicle being higher than the third threshold temperature.

10. A vehicle system, comprising:
a first valve connecting to each other two or more of cooling lines among a battery pack cooling line, an automotive storage device cooling line, a motor cooling line, a radiator cooling line, and a chiller cooling line;
a second valve connecting the motor cooling line to an automotive storage device heating line or to the radiator cooling line; and
a heat management system configured to control the first valve and the second valve with respect to circulating coolant through the cooling lines in order of the motor cooling line, the automotive storage device heating line, the radiator cooling line, a first chiller cooling line, the battery pack cooling line, and the motor cooling line, in response to a temperature of a vehicle being lower than a first threshold temperature.

11. The system of claim 10, wherein the heat management system is configured to control the first valve and the second valve with respect to circulating coolant in order of the automotive storage device cooling line, the motor cooling line, the radiator cooling line, the first chiller cooling line, the battery pack cooling line, and the automotive storage device cooling line in response to the temperature of the vehicle being higher than the first threshold temperature.

12. The system of claim 10, wherein the heat management system is configured to drive a chiller and a radiator, and to control the first valve and the second valve with respect to circulating coolant in order of the battery pack cooling line, the first chiller cooling line, and the battery pack cooling line, and the coolant to be circulated in order of the automotive storage device cooling line, the motor cooling line, the radiator cooling line, and the automotive storage device cooling line, in response to the temperature of the vehicle being higher than a second threshold temperature that is higher than the first threshold temperature.

13. The system of claim 10, wherein the temperature of the vehicle corresponds to a temperature of an automotive storage device, and
the heat management system is configured to drive a chiller and a radiator, and to control the first valve and the second valve with respect to circulating coolant in order of the battery pack cooling line, the first chiller cooling line, and the battery pack cooling line, and the coolant to be circulated in an order of the automotive storage device cooling line, the motor cooling line, the radiator cooling line, a second chiller cooling line, and the automotive storage device cooling line, in response to the temperature of the automotive storage device being higher than a third threshold temperature that is higher than the first threshold temperature.

14. The system of claim 13, wherein the automotive storage device is configured to control an operation of the automotive storage device to be in a throttling mode in response to the temperature of the automotive storage device being higher than the third threshold temperature that is higher than the first threshold temperature.

15. The system of claim 10, wherein the temperature of the vehicle corresponds to a temperature of a motor, and
the heat management system is configured to drive a chiller and a radiator, and to control the first valve and the second valve with respect to circulating coolant in order of the battery pack cooling line, the first chiller cooling line, and the battery pack cooling line, and with respect to circulating the coolant in order of the automotive storage device cooling line, the motor cooling line, the radiator cooling line, a second chiller cooling line, and the automotive storage device cooling line, in response to the temperature of the motor being higher than a fourth threshold temperature that is higher than the first threshold temperature.

16. A vehicle, comprising:
a first valve connecting two or more of cooling lines among a battery pack cooling line, an automotive storage device cooling line, a motor cooling line, a radiator cooling line, and a chiller cooling line;
a second valve connecting the motor cooling line to an automotive storage device heating line or to the radiator cooling line;
a vehicle control unit configured to generate first path information with respect to connecting the battery pack cooling line to the automotive storage device cooling line, connecting the motor cooling line to the radiator cooling line, the motor cooling line being connected to the automotive storage device cooling line, and connecting the radiator cooling line to a first chiller cooling line, the first chiller cooling line being connected to the battery pack cooling line, in response to a temperature of the vehicle being higher than a first threshold temperature; and
a heat management system configured to control the first valve and the second valve with respect to circulating coolant through the cooling lines based on the first path information.

17. The vehicle of claim 16, wherein the vehicle control unit is configured to generate second path information with respect to connecting the battery pack cooling line to the motor cooling line, the motor cooling line to the automotive storage device heating line, and the radiator cooling line to the first chiller cooling line, the radiator cooling line being connected to the automotive storage device heating line, the first chiller cooling line being connected to the battery pack cooling line, in response to the temperature of the vehicle being lower than the first threshold temperature,
and the heat management system is configured to control the first valve and the second valve with respect to circulating coolant through the cooling lines based on the second path information.

18. The vehicle of claim 16, wherein the vehicle control unit is configured to generate third path information with respect to connecting the battery pack cooling line to the first chiller cooling line, the motor cooling line to the automotive storage device cooling line to the radiator cooling line, and the radiator cooling line to the automotive storage device cooling line, in response to the temperature of the vehicle being higher than a second threshold temperature that is higher than the first threshold temperature, and
the heat management system is configured to control the first valve and the second valve to circulate the coolant flowing through the cooling lines based on the third path information.

19. The vehicle of claim 16, wherein
the temperature of the vehicle corresponds to a temperature of the automotive storage device, and
the automotive storage device is configured to provide an alarm signal to the vehicle control unit to indicate that the automotive storage device enters a throttling mode, in response the temperature of the automotive storage device being higher than a third threshold temperature that is higher than the first threshold temperature.

20. The vehicle of claim 19, wherein
the vehicle control unit is configured to generate fourth path information with respect to connecting the battery pack cooling line to the first chiller cooling line, the motor cooling line to the automotive storage device cooling line to the radiator cooling line, the radiator cooling line to a second chiller cooling line, and the second chiller cooling line to the automotive storage device cooling line, in response to the alarm signal, and
the heat management system is configured to control the first valve and the second valve with respect to circulating coolant through the cooling lines based on the fourth path information.
